(19) United States
(12) Patent Application Publication
(10) Pub. No.: US 2025/0232813 A1
(43) Pub. Date: Jul. 17, 2025

(54) NONVOLATILE MEMORY DEVICE REDUCING A NUMBER OF PROGRAM BIT LINES AND PROGRAM METHOD THEREOF

(71) Applicant: SAMSUNG ELECTRONICS CO., LTD., Suwon-si (KR)

(72) Inventors: Sangwon Kim, Suwon-si (KR); Joonsuc Jang, Suwon-si (KR); Yejin Park, Suwon-si (KR); Taeyun Lee, Suwon-si (KR)

(21) Appl. No.: 19/019,083

(22) Filed: Jan. 13, 2025

(30) Foreign Application Priority Data
Jan. 16, 2024 (KR) 10-2024-0006961
May 14, 2024 (KR) 10-2024-0062882

(51) Int. Cl. G11C 16/10; G11C 16/04; G11C 16/08; G11C 16/24; G11C 16/30; G11C 16/34

(52) U.S. Cl. CPC G11C 16/10; G11C 16/0483; G11C 16/08; G11C 16/24; G11C 16/3459; G11C 16/30

(57) ABSTRACT

An example method of programming a non-volatile memory device for programming memory cells with a plurality of target states includes executing a first program loop, and after executing the first program loop, executing a second program loop. In the first program loop, a first program voltage is applied to a word line based on bit lines of first memory cells programmed to a first target state being set to an inhibitory bit line voltage. In the second program loop, a second program voltage is applied to the word line based on the bit lines of the first memory cells being set to a program bit line voltage.

### CROSS-REFERENCE TO RELATED APPLICATIONS

This application claims priority under 35 U.S.C. § 119 to Korean Patent Application No. 10-2024-0006961 filed on Jan. 16, 2024, and Korean Patent Application No. 10-2024-0062882 filed on May 14, 2024, in the Korean Intellectual Property Office, the disclosures of which are incorporated by reference herein in their entireties.

### BACKGROUND

Semiconductor memory devices can be broadly divided into volatile memory and non-volatile memory. Volatile memory (for example, DRAM or SRAM) has fast reading and writing speeds, but stored data is lost when the power supply is cut off. On the other hand, non-volatile memory such as NAND flash memory can retain stored data even if the power supply is interrupted. Recently, vertical NAND flash memory devices that are stacked in three dimensions to improve integration have become common.

As the generations of vertical NAND flash memory change, the number of word lines increases. Accordingly, the deterioration of pass disturbance that occurs during program operation becomes more severe. Generally, during the program operation, a bit line inhibit voltage is provided only to the bit lines of memory cells identified as program pass. In other words, during the program operation, the program bit line voltage is applied to the bit lines of all memory cells except for memory cells identified as program pass. Under these conditions, memory cells connected to the bit line provided with the program bit line voltage and connected to an unselected word line are exposed to pass disturbance by the pass voltage.

Additionally, in the case of a cell string in which the program bit line voltage is provided to the bit line, a relatively large capacitance is formed between the word line and the channel. As the number of cell strings to which the program bit line voltage is supplied during program operation increases, a problem may occur in which power required for word line setup increases due to an increase in capacitance. Therefore, there is a need for a technology that can solve the problem of pass disturbance or power increase without deteriorating the performance of the flash memory device during program operation.

### SUMMARY

The present disclosure relates to a non-volatile memory device that can reduce pass disturbance by reducing the number of program bit lines during program operation without deteriorating performance, and a non-volatile memory device and programming method thereof that can reduce power consumption due to capacitance, which increases in proportion to the number of program bit lines during the program operation.

In general, according to some aspects, a method of programming a non-volatile memory device for programming memory cells with a plurality of target states comprises executing a first program loop in which a first program voltage is applied to a word line while bit lines of first memory cells programmed to a first target state are set to an inhibitory bit line voltage, and after executing the first program loop, executing a second program loop in which a second program voltage is applied to the word line while the bit lines of the first memory cells are set to the program bit line voltage.

In general, according to some aspects, a non-volatile memory device comprises a cell array including memory cells connected to a plurality of bit lines, a row decoder configured to transfer a program voltage or a pass voltage to word lines of the memory cells during a program operation, a page buffer configured to set the plurality of bit lines to a program bit line voltage or an inhibitory bit line voltage, and a control circuit configured to control the page buffer and the row decoder to provide the inhibit bit line voltage to bit lines of the first memory cells during an inhibit loop period including an initial program loop of the first memory cells programmed to a first target state, and to provide the program bit line voltage to the bit lines of the first memory cells during a program loop period following the inhibit loop period.

In general, according to some aspects, a method of programming a non-volatile memory device for programming selected memory cells to a plurality of target states comprises executing at least one program loop with bit lines of memory cells programmed to a first target state set to an inhibitory bit line voltage during a first loop period, and executing a plurality of program loops with bit lines of memory cells programmed to the first target state set to a program bit line voltage during a second loop period following the first loop period.

### BRIEF DESCRIPTION OF THE DRAWINGS

The above and other objects and features of the present disclosure will become apparent by describing in detail implementations thereof with reference to the accompanying drawings.

FIG. 1 is a block diagram showing an example of a non-volatile memory device.

FIG. 2 is a circuit diagram showing an example structure of a memory block constituting the cell array of FIG. 1.

FIG. 3 is a table showing example bit line voltages of memory cells corresponding to each target state for each program loop of the nonvolatile memory device of FIG. 1.

FIG. 4 is a diagram illustrating example pass disturbance in a cell string provided with a program bit line voltage and a cell string provided with an inhibitory bit line voltage.

FIG. 5 is an example timing diagram showing the program voltage and bit line voltage for each program loop of memory cells programmed to the first target state P1, and whether the verification operation is activated.

FIG. 6 is an example timing diagram showing the program voltage and bit line voltage for each program loop of memory cells programmed to the third target state P3, and whether the verification operation is activated.

FIG. 7 is an example timing diagram showing the program voltage and bit line voltage for each program loop of memory cells programmed to the seventh target state P7, and whether the verification operation is activated.

FIG. 8 is a flowchart showing an example of a method of programming selected memory cells according to the procedure defined in the table of FIG. 3.

FIG. 9 is an example graph showing why the start loop in which the program bit line voltage described in FIG. 3 is applied must be faster than the loop in which the verification operation begins.

FIG. 10 is an example diagram showing changes in threshold voltage of memory cells corresponding to each curve in FIG. 9.

FIG. 11 is a block diagram showing an example of a non-volatile memory device.

FIG. 12 is an example graph showing the number of program bit lines reduced according to the selective programming method.

FIG. 13 shows the waveform of an example program voltage pulse provided to selected memory cells in each program loop when applying the voltage offset.

FIG. 14 is an example graph showing the change in the magnitude of the program voltage to which the voltage offset is applied according to the program loop.

FIG. 15 is a flowchart showing an example of a programming method performed in the non-volatile memory device of FIG. 11.

FIG. 16 is a block diagram showing an example of a non-volatile memory device.

FIG. 17 shows the form of an example program voltage pulse provided to selected memory cells in each program loop when applying the pulse width offset.

FIG. 18 is a flowchart showing an example of a programming method performed in the non-volatile memory device of FIG. 16.

FIG. 19 is a diagram illustrating example memory cells comprised by the cell string CS of FIG. 2 and their program order.

### DETAILED DESCRIPTION

It is to be understood that both the foregoing general description and the following detailed description are exemplary. Reference signs are indicated in detail in some implementations, examples of which are indicated in the reference drawings. Wherever possible, the same reference numbers are used in the description and drawings to refer to the same or like parts.

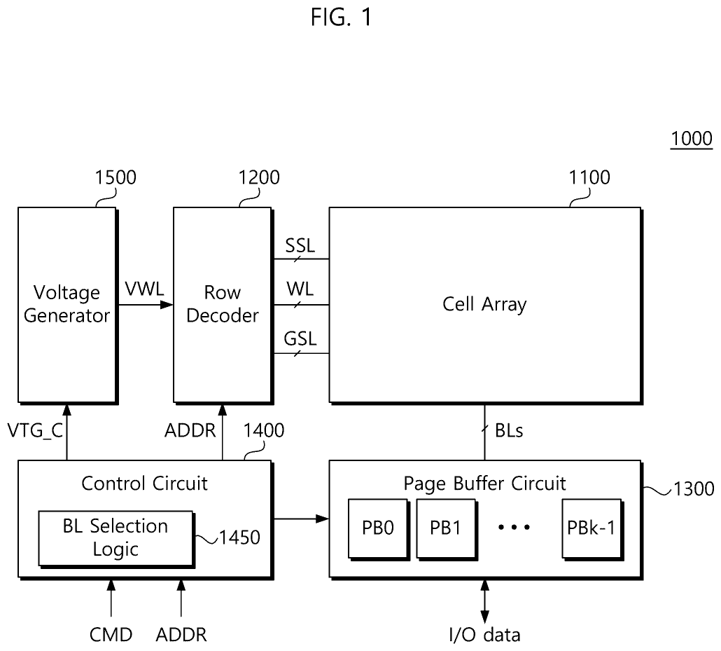

FIG. 1 is a block diagram showing an example of a non-volatile memory device. Referring to FIG. 1, the non-volatile memory device 1000 may include a cell array 1100, a row decoder 1200, a page buffer circuit 1300, a control circuit 1400, and a voltage generator 1500.

The cell array 1100 is connected to the row decoder 1200 through word lines WLs or selection lines SSL and GSL. The cell array 1100 is connected to the page buffer circuit 1300 through bit lines BLs. The cell array 1100 may include a plurality of NAND cell strings. A channel of each cell string may be formed in a direction perpendicular to a substrate. The cell array 1100 will include a plurality of memory cells forming the NAND cell string. A plurality of memory cells can be programmed, erased, and sensed by voltage provided to bit lines BLs or word lines WLs. Program operations can be performed on a page-by-page basis, and erase operations can be performed on a block-by-block basis.

The row decoder 1200 may select one of the memory blocks of the cell array 1100 in response to the address ADDR. The row decoder 1200 may select one of the word lines of the selected memory block in response to the address ADDR. The row decoder 1200 delivers a word line voltage VWL corresponding to the operation mode to the word line of the selected memory block. During the program operation, the row decoder 1200 delivers a program voltage Vpgm and a verification voltage Vvfy to the selected word line and a pass voltage Vpass to unselected word lines. During a read operation, the row decoder 1200 delivers a read voltage Vrd to the selected word line and a read pass voltage Vread to the unselected word lines.

The page buffer circuit 1300 operates as a write driver or a sense amplifier. During the program operation, the page buffer circuit 1300 transmits a bit line voltage corresponding to data to be programmed to the bit lines BLs of the cell array 1100. For example, the page buffer circuit 1300 applies a program bit line voltage (e.g., 0V) to the bit line of the cell to be programmed. On the other hand, an inhibitory bit line voltage (e.g., 2V) is applied to the bit line of the program-inhibited cell. During the program operation, the channel of the cell string to which the inhibitory bit line voltage is provided is floated by the string select transistor SST that is shut-off. And when the program voltage or pass voltage is applied, the floating channel is boosted according to the coupling effect. Channel boosting may lower the potential difference between the word line and the channel, causing the program to be blocked.

During the program operation, the page buffer circuit 1300 may set the bit lines of selected memory cells to the inhibitory bit line voltage up to a specific loop count even before program completion. Among the memory cells, memory cells that are programmed to the target state P5 will be described. Here, it is assumed that the memory cells are triple level cell TLC with a total of eight target states: an erase state E and program states P1, P2, P3, P4, P5, P6, and P7. However, the advantages of the present disclosure can be equally applied to MLC, QLC, etc.

In each program loop, a program voltage Vpgm is applied to the word lines of memory cells to be programmed to the target state P5. At this time, the inhibitory bit line voltage (Vbl_inh, or VDD) will be applied to the bit lines of memory cells to be programmed to the target state P5 from the first loop Loop1 to the sixth loop Loop6. And in the seventh loop Loop7 to the twelfth loop Loop12, the program bit line voltage (Vbl_pgm, or 0V) will be applied to the bit lines of memory cells to be programmed to the target state P5. And in the seventh loop Loop7 to the twelfth loop Loop12 that are performed after the program is completed, the bit lines of these memory cells will be set to the inhibitory bit line voltage (Vbl_inh, or VDD).

The page buffer circuit 1300 can provide an inhibitory bit line voltage to the bit lines of memory cells to be programmed from the first program loop (Loop1) to a specific program loop. Accordingly, the number of memory cells to which the program bit line voltage is applied in one program loop is dramatically reduced. As the number of memory cells to which the inhibitory bit line voltage Vbl_inh is applied increases, degradation due to pass disturbance can be reduced, and power consumption required for word line setup can also be reduced.

The control circuit 1400 controls the page buffer circuit 1300, the row decoder 1200, and the voltage generator 1500 in response to a command CMD provided from the outside. The control circuit 1400 may control the voltage generator 1500, the page buffer circuit 1300, and the row decoder 1200 to perform program, read, and erase operations on the selected memory cell according to the command CMD. To this end, the control circuit 1400 may provide an address ADDR to the row decoder 1200 and a voltage control signal VTG_C to the voltage generator 1500.

In particular, the control circuit 1400 may include bit line selection logic 1450. The bit line selection logic 1450 may control the page buffer circuit 1300 to set the bit lines of memory cells to the inhibitory bit line voltage (Vbl_inh, or 2V) in the initial program loop during the program operation. Thereafter, the bit line selection logic 1450 controls the page buffer circuit 1300 to apply the program bit line voltage Vbl_pgm to the bit lines of memory cells when a specific program loop designated for each target state is reached. Thereafter, the bit line selection logic 1450 controls the page buffer circuit 1300 to provide the inhibitory bit line voltage Vbl_inh again to the bit lines of memory cells identified as program pass for program verify operation.

For example, memory cells that are programmed to the target state P3 will be considered. The program voltage Vpgm is applied to the word lines of memory cells programmed to the target state P3 in all program loops. In addition, the bit line selection logic 1450 controls the page buffer circuit 1300 to set the bit lines of memory cells programmed to the target state P3 to the inhibitory bit line voltage Vbl_inh in the first to third program loops (Loop1˜Loop3). And the bit line selection logic 1450 controls the page buffer circuit 1300 so that the program bit line voltage Vbl_pgm is applied to the bit lines of memory cells to be programmed to the target state P3 in the fourth to eighth program loops (Loop4˜Loop8). The bit line selection logic 1450 controls the page buffer circuit 1300 to apply the inhibitory bit line voltage Vbl_inh again to the bit lines of memory cells programmed to the target state P3 in the program loop after the eighth loop Loop8 in which all memory cells are programmed.

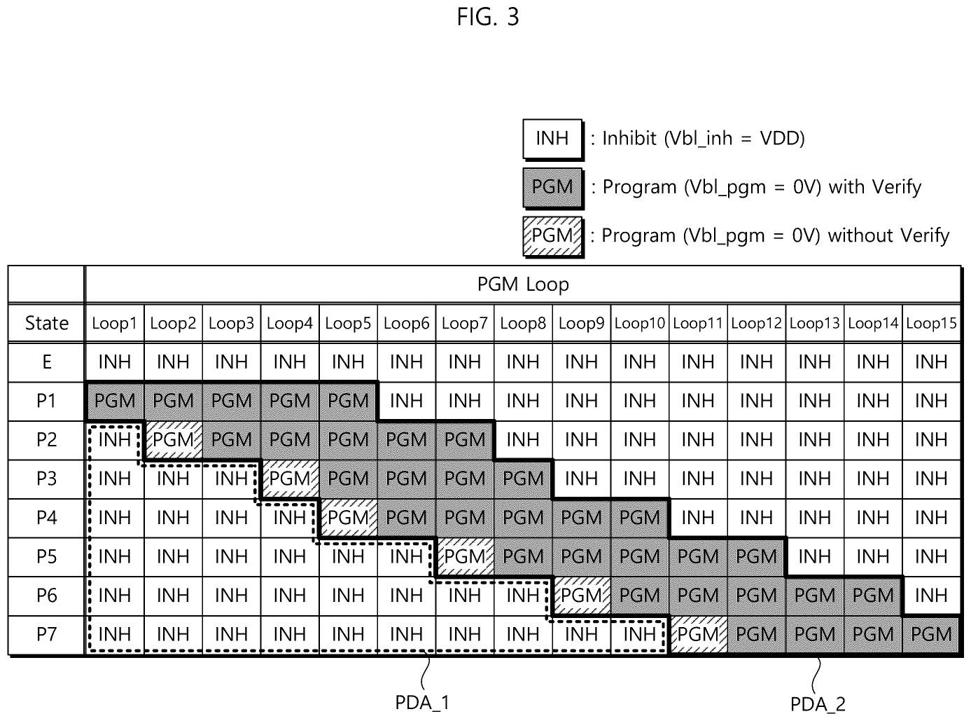

Naturally, the bit line selection logic 1450 will control the page buffer circuit 1300 so that the inhibitory bit line voltage Vbl_inh is provided to the bit lines of memory cells whose target state is the erase state E throughout the entire program loops. And, the page buffer circuit 1300 is controlled so that the program bit line voltage Vbl_pgm is applied from the first program loop to the bit lines of memory cells programmed to the lowest target state (for example, P1 state) among the program states. The selective bit line voltage setting for each loop using the bit line selection logic 1450 will be described in more detail with reference to FIG. 3 described later.

The voltage generator 1500 supplies various types of word line voltages VWL to be supplied to each word line and to the bulk (e.g., well area) where memory cells are formed under the control of the control circuit 1400. Word line voltages to be supplied to each word line include a program voltage Vpgm, a pass voltage Vpass, and selection read voltage and un-selection read voltages.

The bit line selection logic 1450 and the page buffer circuit 1300 provide an inhibitory bit line voltage Vbl_inh to the bit lines of memory cells to be programmed from the first program loop to a specific program loop during the program operation. Accordingly, the number of memory cells to which the program bit line voltage Vbl_pgm is applied in one program loop is dramatically reduced. As the number of memory cells to which the inhibitory bit line voltage Vbl_inh is applied increases, degradation due to pass disturbance can be reduced, and power consumption required for word line setup can also be reduced.

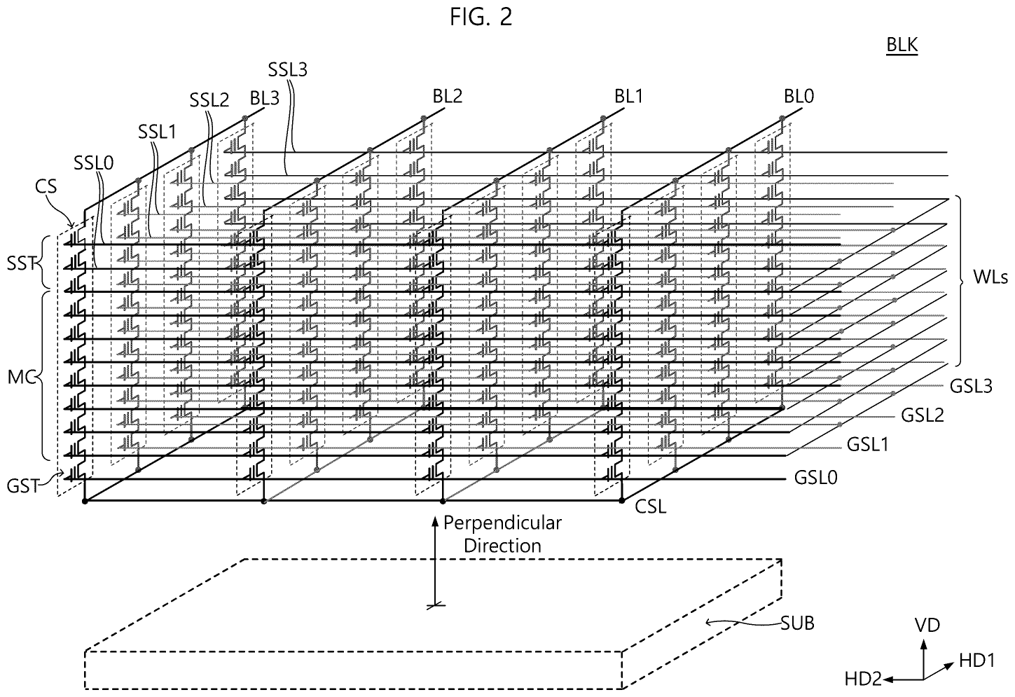

FIG. 2 is a circuit diagram showing an example structure of a memory block constituting the cell array of FIG. 1. Referring to FIG. 2, cell strings CSs are formed between the bit lines BL0, BL1, BL2, and BL3 and the common source line CSL to form the memory block BLK.

A plurality of cell strings are formed between the bit line BL0 and the common source line CSL. The string select transistor SST of the cell strings CS is connected to the corresponding bit line BL. The ground select transistor GST of the cell strings CS is connected to the common source line CSL. Memory cells MCs are provided between the string select transistor SST and the ground select transistor GST of the cell string CS.

Each of the cell strings CS includes a ground select transistor GST. Ground selection transistors included in the cell strings CS may be controlled by the ground selection line GSL. Alternatively, although not shown, cell strings corresponding to each row may be controlled by different ground selection lines.

The circuit structure of three-dimensional memory cells included in one memory block BLK was briefly described. However, the circuit structure of the illustrated memory block is only a simplified structure for convenience of explanation, and the actual memory block is not limited to the illustrated example. That is, it will be well understood that one physical block may include more semiconductor layers, bit lines BLs, and string selection lines SSLs.

FIG. 3 is a table showing example bit line voltages of memory cells corresponding to each target state for each program loop of the nonvolatile memory device of FIG. 1. Referring to FIG. 3, the page buffer circuit 1300 and the bit line selection logic 1450 provide the program bit line voltage Vbl_pgm only to memory cells that are programmed to some target states among the selected memory cells during a program operation. That is, in one program loop, a program bit line voltage Vbl_pgm is applied to memory cells programmed to the first target state, and an inhibitory bit line voltage Vbl_inh is applied to memory cells programmed to a second target state higher than the first target state. Accordingly, the number of memory cells to which the program bit line voltage Vbl_pgm is provided in one program loop can be minimized. Hereinafter, the advantages of the present disclosure will be explained by taking the case where the memory cells of the non-volatile memory device 1000 are triple level cell TLC as an example. In other words, memory cells may have a total of eight target states including an erase state E and program states P1, P2, P3, P4, P5, P6, and P7.

The page buffer circuit 1300 and the bit line selection logic 1450 may apply an incremental step pulse programming ISPP method to program memory cells. That is, a gradually increasing program voltage Vpgm in each of the plurality of program loops (PGM Loop) will be provided to the word lines of the selected memory cells. At the same time, a pass voltage Vpass is applied to the word lines of the unselected memory cells. At this time, the program bit line voltage Vbl_pgm or the inhibitory bit line voltage Vbl_inh is provided to the bit lines of the memory cells depending on the target state.

The inhibitory bit line voltage Vbl_inh is provided to the bit lines of memory cells whose target state corresponds to the erase state E during all program loops Loop1 to Loop15. In other words, memory cells with a target state of the erased state E must maintain the threshold voltage that is already in the erased state E. Therefore, an inhibitory bit line voltage Vbl_inh must be provided to the bit lines of these memory cells so that the channel is boosted even if the program loop progresses. On the other hand, memory cells whose target state is one of the program states (P1, P2, P3, P4, P5, P6, and P7) can be provided either the program bit line voltage Vbl_pgm or the inhibitory bit line voltage Vbl_inh depending on the loop count.

First, the operation in the first loop Loop1, where the program voltage is first applied to program the selected memory cells, will be described. The inhibitory bit line voltage Vbl_inh is provided to the bit lines of memory cells programmed to the erase state E in the first loop Loop1. And the program bit line voltage Vbl_pgm is provided to the bit lines of memory cells programmed to the first target state P1. At this time, memory cells whose target states are the second to seventh target states P2 to P7 are also set to program inhibition. That is, the bit lines of memory cells programmed to the target states P2, P3, P4, P5, P6, and P7 are set to the inhibitory bit line voltage Vbl_inh.

In the first loop Loop1, the memory cells to which the program bit line voltage Vbl_pgm is provided are only memory cells that are programmed to the first target state P1. Therefore, if the target state is evenly distributed through randomization, the number of memory cells in which the potential difference between the word line and the channel rises to the program level in the first loop Loop1 section corresponds to about ⅛ of the selected memory cells. Accordingly, pass disturbance occurring in memory cells programmed to the target states P2, P3, P4, P5, P6, and P7 can be dramatically reduced. In addition, as the capacitance between the word line and the channel of the selected memory cells decreases, power consumption for setting up the word line voltage is expected to decrease.

In the second loop Loop2, the inhibitory bit line voltage Vbl_inh is provided to the bit line of the memory cell programmed to the erase state E. Additionally, a program bit line voltage Vbl_pgm is provided to the bit lines of memory cells programmed to the first target state P1 and the second target state P2, respectively. At this time, the program verify operation for memory cells programmed to the second target state P2 can be skipped. And memory cells programmed to the third to seventh target states P3 to P7 are set to be program-inhibited. In other words, the inhibitory bit line voltage Vbl_inh is provided to the bit lines of memory cells that are programmed to each of the target states P3, P4, P5, P6, and P7.

Memory cells to which the program bit line voltage Vbl_pgm is provided in the second loop Loop2 are memory cells that are programmed to the first target stage P1 and the second target state P2. Therefore, if the target state is evenly distributed through randomization, the number of memory cells in which the potential difference between word line and channel rises to the program level in the second loop Loop2 section is about 2/8 of the selected memory cells. However, in the first loop Loop1, there will be memory cells that are set to be program inhibited by program verification. Therefore, in reality, the number of memory cells in which the potential difference between the word line and the channel rises to the program level in the second loop Loop2 section may be less than about 2/8 of all memory cells. Ultimately, pass disturbance occurring in memory cells programmed to the target states P3, P4, P5, P6, and P7 is reduced. In addition, as the capacitance between the word line and the channel of the selected memory cells decreases, the power consumption for setting up the word line voltage will also decrease.

In the third loop Loop3, the program bit line voltage Vbl_pgm is provided to the bit lines of memory cells programmed to the first target state P1 and the second target state P2, respectively. At this time, unlike the second loop Loop2, a program verify operation for memory cells programmed to the second target state P2 is activated. And the inhibitory bit line voltage Vbl_inh is provided to the bit lines of memory cells that are programmed to the erase state E and the target states P3, P4, P5, P6, and P7.

In the fourth loop Loop4, the program bit line voltage Vbl_pgm is provided to the bit lines of memory cells programmed to the first to third target states P1 to P3. At this time, the program verify operation for memory cells programmed to the third program state P3 is deactivated. And the inhibitory bit line voltage Vbl_inh is provided to the bit lines of memory cells that are programmed to the erase state E and the target states P4, P5, P6, and P7. In the fourth loop Loop4, the number of memory cells in which the potential difference between word lines and channels rises to the program level may be less than ⅜ of the selected memory cells. Ultimately, pass disturbance occurring in memory cells programmed to the target states P4, P5, P6, and P7 and power consumption for setting up the word line voltage will also be reduced.

In the fifth loop Loop5, the program bit line voltage Vbl_pgm is provided to the bit lines of memory cells programmed to the first to fourth target states P1 to P4. At this time, the program verify operation for memory cells programmed to the fourth target state P4 is deactivated. And the inhibitory bit line voltage Vbl_inh is provided to the bit lines of memory cells that are programmed to the erase state E and the target states P5, P6, and P7. Accordingly, the number of memory cells in the fifth loop Loop5 whose potential difference between word lines and channels rises to the program level may be less than 4/8 of the selected memory cells. Ultimately, pass disturbance occurring in memory cells programmed to the target states P5, P6, and P7 and power consumption for setting up the word line voltage will also be reduced.

In the sixth loop Loop6, the program to the first target state P1 is terminated, and the program bit line voltage Vbl_pgm is provided to the bit lines of the memory cells programmed to the second to fourth target states P2 to P4. At this time, unlike the fifth loop Loop5, the program verify operation for memory cells programmed to the fourth target state P4 is activated. And the inhibitory bit line voltage Vbl_inh is provided to the bit lines of memory cells that are programmed to the erase state E and the target states P5, P6, and P7.

In the seventh loop Loop7, the program bit line voltage Vbl_pgm is provided to the bit lines of memory cells programmed to the second to fifth target states P2 to P5. At this time, the program verify operation for memory cells programmed to the fifth target state P5 is deactivated. And the inhibitory bit line voltage Vbl_inh is provided to the bit lines of memory cells that are programmed to the erase state E and the target states P1, P6, and P7.

In the eighth loop Loop8, the program operation to the second target state P2 is terminated, and the program bit line voltage Vbl_pgm is provided to the bit lines of the memory cells programmed to the third to fifth target states P3 to P5. Unlike the seventh loop Loop7, the program verify operation for memory cells programmed to the fifth target state P5 is activated. And the inhibitory bit line voltage Vbl_inh is provided to the bit lines of memory cells programmed to the erase state E, the first to second target states P1 to P2, and the sixth to seventh target states P6 to P7.

In the ninth loop Loop9, the program bit line voltage Vbl_pgm is provided to the bit lines of memory cells programmed to the fourth to sixth program states P4 to P6. At this time, the program verify operation for memory cells programmed to the sixth target state P6 is deactivated. And the inhibitory bit line voltage Vbl_inh is provided to the bit lines of memory cells that are programmed to the erase state E and the target states P1, P2, P3, and P7. Memory cells to which the program bit line voltage Vbl_pgm is provided in the ninth loop Loop9 are memory cells that are programmed to the fourth to sixth target states P4, P5, and P6. Accordingly, in the ninth loop Loop9, the number of memory cells in which the potential difference between word lines and channels rises to the program level may be less than ⅜ of the selected memory cells.

In the tenth loop Loop10, like the ninth loop Loop9, the program bit line voltage Vbl_pgm is provided to the bit lines of memory cells programmed to the fourth to sixth target states P4 to P6. On the other hand, the program verify operation for memory cells programmed to the sixth target state P6 is activated. And the inhibitory bit line voltage Vbl_inh is provided to the bit lines of memory cells that are programmed to the erase state E and the target states P1, P2, P3, and P7.

Memory cells to which the program bit line voltage Vbl_pgm is provided in the tenth loop Loop10 are memory cells that are programmed to the third to fifth target states P4, P5, and P6. When the program verification results are reflected, the number of memory cells in which the potential difference between word lines and channels rises to the program level in the tenth loop Loop10 may be less than that in the ninth loop Loop9. Ultimately, even in the tenth loop Loop10, pass disturbance occurring in memory cells programmed to the target state P7 can be ignored. In addition, as the capacitance between the word line and the channel of the selected memory cells decreases, the power consumption for setting up the word line voltage will also decrease.

In the eleventh loop Loop11, the program bit line voltage Vbl_pgm is provided to the bit lines of memory cells programmed to the fifth to seventh target states P5 to P7. At this time, the program verify operation for memory cells programmed to the seventh target state P7 is deactivated. And memory cells programmed to the erase state E and the first to fourth target states P1 to P4 are set to be program inhibited.

In the twelfth loop Loop12, like the eleventh loop Loop11, the program bit line voltage Vbl_pgm is provided to the bit lines of memory cells programmed to the fifth to seventh target states P5 to P7. On the other hand, a program verify operation for memory cells programmed to the seventh target state P7 is activated. And the inhibitory bit line voltage Vbl_inh is provided to the bit lines of memory cells that are programmed to the erase state E and the target states P1, P2, P3, and P4.

In the thirteenth loop Loop13, the program bit line voltage Vbl_pgm is provided to the bit lines of memory cells programmed to the sixth to seventh target states P6 to P7. And memory cells programmed to the erase state E and the first to fifth target states P1 to P5 are set to be program inhibited.

In the fourteenth loop Loop14, the program bit line voltage Vbl_pgm is provided to the bit lines of memory cells programmed to the 6th to 7th target states P5 to P7, similarly to the thirteenth loop Loop13. And the inhibitory bit line voltage Vbl_inh is provided to the bit lines of memory cells that are programmed to the erase state E and the first to fifth target states P1 to P5.

In the fifteenth loop Loop15, the program bit line voltage Vbl_pgm is provided to the bit lines of memory cells programmed to the seventh target state P7. And the inhibitory bit line voltage Vbl_inh is provided to the bit lines of memory cells that are programmed to the erase state E and the target states P1 to P6.

In the above, the characteristics of the bit line voltage applied to memory cells for each target state in each program loop have been described. However, the advantages of the present disclosure may be explained for each target state P1 to P7 as follows.

Memory cells programmed to the first target state P1 are provided with the program bit line voltage Vbl_pgm in the first to fifth loops Loop1 to Loop5. Additionally, the inhibitory bit line voltage Vbl_inh may be provided to the memory cells programmed to the first target state P1 in the 6th to 15th loops Loop6 to Loop15.

The inhibitory bit line voltage Vbl_inh is provided to the bit lines of memory cells programmed to the second target state P2 in the first loop Loop1. And the program bit line voltage Vbl_pgm is provided to the bit lines of the memory cells programmed to the second target state P2 in the second to seventh loops Loop2 to Loop7. And, the inhibitory bit line voltage Vbl_inh is provided to the bit lines of the memory cells programmed to the second target state P2 in the 8th to 15th loops Loop8 to Loop15. At this time, the program verify operation for memory cells programmed to the second target state P2 in the second loop Loop2 is skipped.

The inhibitory bit line voltage Vbl_inh is provided to the bit lines of memory cells programmed to the third target state P3 in the first to third loops Loop1 to Loop3. And the program bit line voltage Vbl_pgm is provided to the bit lines of the memory cells programmed to the third target state P3 in the fourth to eighth loops Loop4 to Loop8. Additionally, the inhibitory bit line voltage Vbl_inh is provided to the bit lines of memory cells programmed to the third target state P3 in the 9th to 15th loops Loop9 to Loop15. At this time, the program verify operation for memory cells programmed to the third target state P3 in the fourth loop Loop4 may be skipped.

The inhibitory bit line voltage Vbl_inh is provided to the bit lines of memory cells programmed to the fourth target state P4 in the first to fourth loops Loop1 to Loop4. And in the fifth to tenth loops Loop5 to Loop10, the program bit line voltage Vbl_pgm is provided to the bit lines of memory cells programmed to the fourth target state P4. Additionally, the inhibitory bit line voltage Vbl_inh is provided to the bit lines of memory cells programmed to the fourth target state P4 in the 11th to 15th loops Loop11 to Loop15. At this time, the program verify operation for memory cells programmed to the fourth target state P4 in the fifth loop Loop5 may be skipped.

The inhibitory bit line voltage Vbl_inh is provided to the bit lines of memory cells programmed to the fifth target state P5 in the first to sixth loops Loop1 to Loop6. And in the 7th to 12th loops Loop7 to Loop12, the program bit line voltage Vbl_pgm is provided to the bit lines of memory cells programmed to the fifth target state P5. Additionally, the inhibitory bit line voltage Vbl_inh is provided to the bit lines of memory cells programmed to the fifth target state P5 in the 13th to 15th loops Loop13 to Loop15. At this time, the program verify operation for memory cells programmed to the fifth target state P5 in the seventh loop Loop7 may be skipped.

The inhibitory bit line voltage Vbl_inh is provided to the bit lines of the memory cells programmed to the sixth target state P6 in the first to eighth loops Loop1 to Loop8. And in the 9th to 14th loops Loop9 to Loop14, the program bit line voltage Vbl_pgm is provided to the bit lines of memory cells programmed to the sixth target state P6. Additionally, the inhibitory bit line voltage Vbl_inh is provided to the bit lines of the memory cells programmed to the sixth target state P6 in the fifteenth loop Loop15. At this time, the program verify operation for memory cells programmed to the sixth target state (P6) in the ninth loop Loop9 may be skipped.

The inhibitory bit line voltage Vbl_inh is provided to the bit lines of memory cells programmed to the seventh target state P7 in the first to tenth loops Loop1 to Loop10. And in the 11th to 15th loops Loop11 to Loop15, the program bit line voltage Vbl_pgm is provided to the bit lines of memory cells programmed to the seventh target state P7. At this time, in the 11th loop Loop11, the program verify operation for memory cells programmed to the 7th target state P7 may be skipped.

In the table shown, an area PDA_2 where pass disturbance occurs is shown as a boundary with a thick straight line. In addition, even though the program has not been completed, the area PDA_1 where pass disturbance is blocked is indicated by a dotted line as the inhibitory bit line voltage Vbl_inh is provided to the bit lines of the memory cells. In some implementations, in a program operation for memory cells having an arbitrary target state, the inhibitory bit line voltage Vbl_inh is provided until a specific loop is reached. And after a specific loop, the program bit line voltage Vbl_pgm is provided to the bit lines of these memory cells. Accordingly, as the program bit line voltage is applied to the bit line in one program loop, the number of memory cells exposed to pass disturbance is dramatically reduced. That is, there may be the area PDA_1 where pass disturbance is blocked.

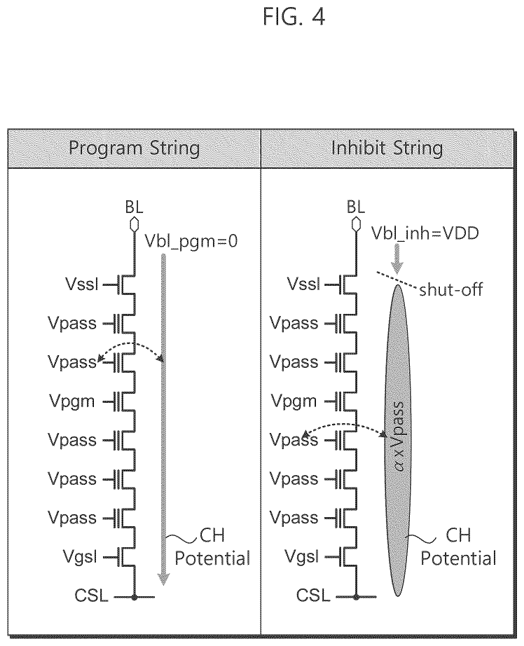

FIG. 4 is a diagram illustrating example pass disturbance in a cell string provided with a program bit line voltage and a cell string provided with an inhibitory bit line voltage. Referring to FIG. 4, a cell string provided with the program bit line voltage Vbl_pgm will be referred to as a program string, and a cell string provided with an inhibitory bit line voltage Vbl_inh will be referred to as an inhibit string. A string select line voltage Vssl, for example, 3V, is provided to each of the program string and the inhibit string. In addition, a program voltage Vpgm is applied to a selected word line of each of the program string and the inhibit string, a pass voltage Vpass is applied to a non-selected word line, and 0 V can be applied as a ground select voltage Vgsl.

In the above-described conditions, the bit line of the program string is fixed to 0V or ground voltage by the program bit line voltage Vbl_pgm. Accordingly, the channel potential of the program string is fixed to the ground level. In this case, the potential difference between the word lines of the memory cells connected to the unselected word lines and the channel becomes relatively high. Therefore, as the pass voltage is applied, a pass disturbance in which charges flow into the nitride film may occur.

On the other hand, in the case of an inhibit string, the inhibitory bit line voltage Vbl_inh at the power supply voltage VDD level is provided to the bit line. Then, the string select transistor SST is shut-off, and the channel of the inhibit string is in a floating state where it is electrically blocked from the bit line. At this time, when the program voltage or the pass voltage is provided to the word lines, the channel potential of the inhibit string rises to the boosting level (α×Vpass) due to the coupling effect. Accordingly, the potential difference between the word lines of the memory cells and the channels is reduced and charge injection into the nitride film does not occur. Therefore, pass disturbance is blocked.

By increasing the number of inhibit bit lines for each loop of FIG. 3 described above, the occurrence of pass disturbance can be drastically reduced. And as the number of inhibit bit lines increases, the word line setup power caused by the capacitance between the word line and the channel can be reduced.

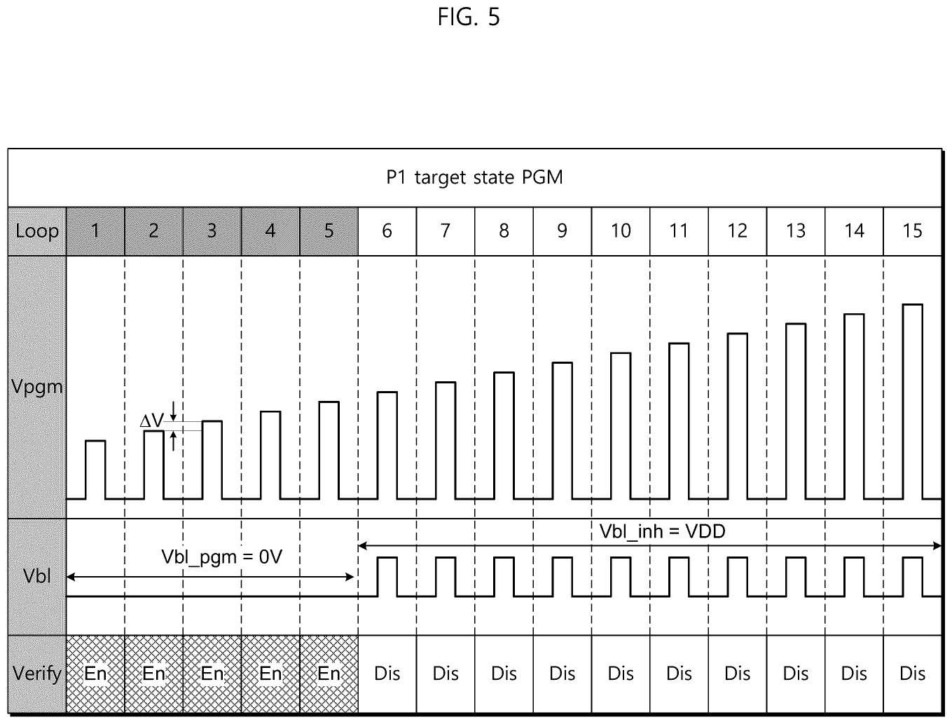

FIG. 5 is an example timing diagram showing the program voltage, bit line voltage, and whether the verification operation is enabled or not for each program loop of memory cells programmed to the first target state P1. Referring to FIG. 5, memory cells programmed to the first target state P1 corresponding to the lowest threshold voltage distribution among the target program states provided with the program bit line voltage Vbl_pgm from the first loop Loop1.

A program voltage Vpgm pulse that increases by an increase step ΔV for each loop is applied to the word lines of memory cells programmed to the first target state P1. At this time, in the first to fifth loop sections Loop1 to Loop5, the program bit line voltage Vbl_pgm (e.g., 0V) is provided to the bit lines of memory cells programmed to the first target state P1. A verification operation is also enabled in the first to fifth loops Loop1 to Loop5 where the program bit line voltage Vbl_pgm is applied. And memory cells that have completed programming according to the verification operation in the first to fifth loop sections Loop1 to Loop5 are set to program inhibit.

In the 6th to 15th loops Loop6 to Loop15, the inhibitory bit line voltage Vbl_inh is provided to the bit lines of memory cells programmed to the first target state P1. In addition, the program verification operation of memory cells programmed to the first target state P1 in the 6th to 15th loops Loop6 to Loop15 will also be disabled.

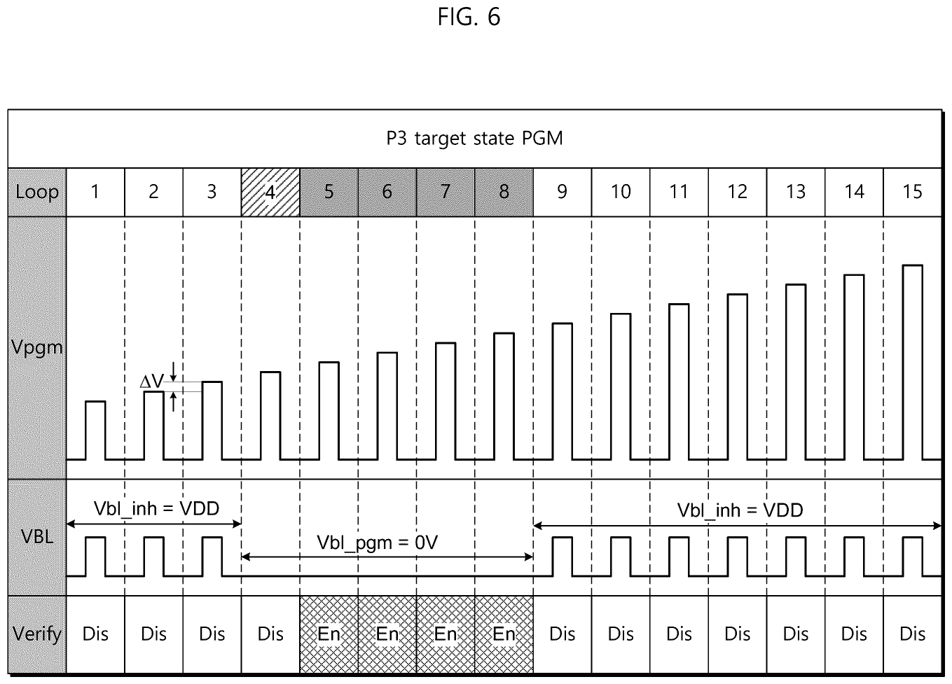

FIG. 6 is an example timing diagram showing the program voltage, bit line voltage, and whether the verification operation is enabled or not for each program loop of memory cells programmed to the third target state P3. Referring to FIG. 6, the program bit line voltage Vbl_pgm is applied to memory cells programmed to the third target state P3 in the period from the fourth loop Loop4 to the eighth loop Loop8.

A program voltage Vpgm pulse that increases by an increase step AV for each loop is applied to the word lines of memory cells programmed to the third target state P3. In the first to third loop sections Loop1 to Loop3, the inhibitory bit line voltage Vbl_inh is provided to the bit lines of memory cells programmed to the third target state P3. The verification operation for memory cells programmed to the third target state P3 in the first to third loop sections Loop1 to Loop3 is also disabled.

A program bit line voltage Vbl_pgm is provided to the bit lines of memory cells programmed to the third target state P3 in the fourth to eighth loop sections Loop4 to Loop8. However, the program verification operation in the fourth loop Loop4 to which the program bit line voltage Vbl_pgm is applied maintains disabled state ‘Dis’. Then, the program verification operation is also enabled ‘En’ in the fifth to eighth loop section Loop5 to Loop8. That is, in the fifth to eighth loop sections Loop5 to Loop8, memory cells that have been programmed above the target threshold voltage after the program voltage Vpgm is applied are identified. And the memory cells that have completed programming are set to program inhibited in subsequent program loops. Here, setting the program operation without verification operation in the fourth loop Loop4 is a measure to reduce over-programming of memory cells programmed to the third target state P3.

In the 9th to 15th loops Loop6 to Loop15, the inhibitory bit line voltage Vbl_inh is provided to the bit lines of memory cells programmed to the third target state P3. In addition, the program verification operation of memory cells programmed to the third target state P3 in the 9th to 15th loops Loop6 to Loop15 will also be disabled.

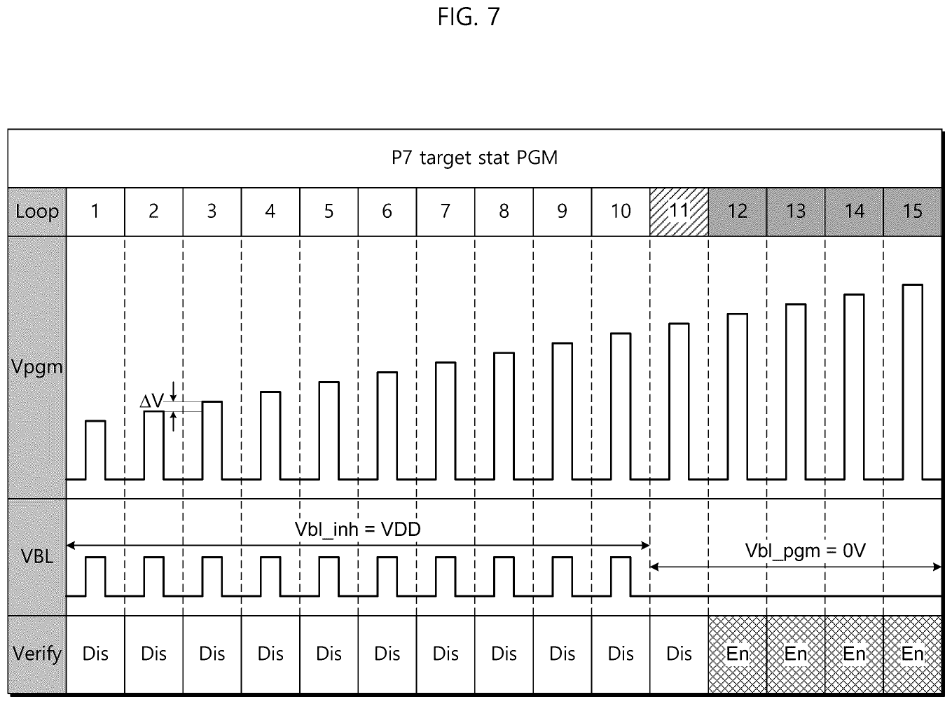

FIG. 7 is an example timing diagram showing the program voltage, bit line voltage and whether the verification operation is enabled or not for each program loop of memory cells programmed to the seventh target state P7. Referring to FIG. 7, the program bit line voltage Vbl_pgm is applied to memory cells programmed to the seventh target state P7 in the section from the 11th loop Loop11 to the 15th loop Loop15.

A program voltage Vpgm pulse that increases by an increase step ΔV for each loop is applied to the word lines of memory cells programmed to the seventh target state P7. In the first to tenth loop sections Loop1 to Loop10, the inhibitory bit line voltage Vbl_inh is provided to the bit lines of memory cells programmed to the seventh target state P7. Verification operations for memory cells programmed to the seventh target state P7 in the first to tenth loop sections Loop1 to Loop10 are disabled ‘Dis’.

A program bit line voltage Vbl_pgm is provided to the bit lines of memory cells programmed to the seventh target state P7 in the 11th to 15th loop sections Loop11 to Loop15. However, the program verification operation in the 11th loop Loop11 to which the program bit line voltage Vbl_pgm is applied remains in the disabled state ‘Dis’. Then, starting from the twelfth loop Loop12, the program verification operation is also Enabled ‘En’. That is, in the 12th to 15th loop sections Loop12 to Loop15, memory cells that have been programmed above the target threshold voltage after the program voltage Vpgm is applied are identified. And these memory cells that have completed programming are set to program inhibited in subsequent program loops. Here, disabling the verification operation in the 11th loop Loop11 is a measure to reduce over-programming of memory cells programmed to the 7th target state P7.

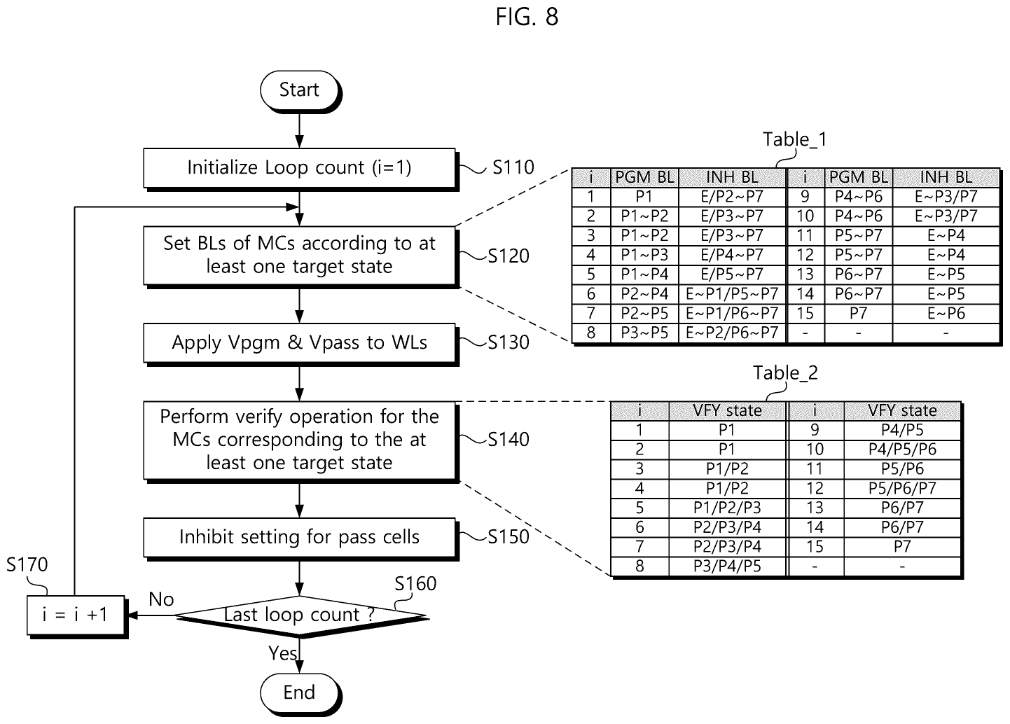

FIG. 8 is a flowchart showing an example of a method of programming selected memory cells according to the procedure defined in the table of FIG. 3. Referring to FIG. 8, among memory cells selected for programming, there are cells that are set as program inhibited in at least one initial program loop.

In step S110, the bit line selection logic 1450 (see FIG. 3) and the page buffer circuit 1300 (see FIG. 3) initialize the loop count (i=1). Here, it is assumed that the loop count required to program the selected memory cells is 15.

In step S120, the bit line selection logic 1450 and the page buffer circuit 1300 set the bit lines of the selected memory cells according to the target state. That is, the bit line selection logic 1450 controls the page buffer circuit 1300 to apply the program bit line voltage Vbl_pgm to the bit lines of memory cells having a specific target state according to the loop count ‘i’. In addition, the bit line selection logic 1450 controls the page buffer circuit 1300 to set the bit lines of memory cells programmed to a target state excluding the specific target state according to the loop number (i) to the inhibit bit line voltage Vbl_inh. For example, when the loop count (i) is ‘l’, the program bit line voltage Vbl_pgm is provided to the bit lines of memory cells programmed to the first target state P1. And the inhibitory bit line voltage Vbl_inh is provided to the bit lines of memory cells programmed to the second to seventh program states P2 to P7 and memory cells having the target state of the erase state E. Target states set as program or inhibit for each loop count ‘i’ are shown in the first table Table_1.

In step S130, the control circuit 1400 controls the voltage generator 1500 and the row decoder 1200 to apply the program voltage Vpgm and the pass voltage Vpass to the word line. Then, the program voltage pulse at a level corresponding to the loop count ‘i’ will be applied to the selected word line.

In step S140, the control circuit 1400 controls the row decoder 1200 and the page buffer circuit 1300 to perform the verification operation for each target state at the corresponding loop count ‘i’. Target states in which the verification operation is enabled in each loop count ‘i’ are displayed in the illustrated second table Table_2. According to the verification operation according to the first table Table_1 and the second table Table_2, in the loop where the program bit line voltage is firstly applied to the memory cells to be programmed to each of the target states P2, P3, P4, P5, P6, and P7, the verification operation is skipped. For example, memory cells programmed to the target state P2 are first provided with the program bit line voltage at the loop count ‘i=2’. However, in the loop count ‘i=2’, the verification operation for memory cells having the target state P2 is skipped. Alternatively, memory cells programmed to the target state P5 receive the program bit line voltage for the first time in the loop count ‘i=7’, but the verification operation is skipped in the loop count ‘i=7’.

In step S150, the control circuit 1400 sets the bit lines of the programmed memory cells to program inhibit according to the result of the verification operation. That is, the inhibitory bit line voltage Vbl_inh is set to be provided to the bit lines of memory cells for which the result of the verification operation is identified as program pass from the subsequent loop count.

In step S160, the control circuit 1400 determines whether the current loop count ‘I’ is the final loop count (for example, 15) set in one program cycle. If it is determined that the current loop count ‘I’ has reached the final loop count (‘Yes’ direction), all programming procedures for the selected memory cells are terminated. On the other hand, if it is determined that the current loop count ‘i’ is not the final loop count (‘No’ direction), the procedure moves to step S170.

In step S170, the control circuit 1400 increases the current loop count ‘i’. Then, the procedure returns to step S120 for ISPP operation corresponding to the increased loop count ‘i+1’.

In some implementations, the program bit line voltage is provided to only some of the memory cells selected for programming. Accordingly, pass disturbance of memory cells that occurs depending on the number of memory cells to which the program bit line voltage Vbl_pgm is provided can be reduced. Additionally, word line setup power may also decrease as the capacitance between the word line and the channel is reduced based on the number of memory cells to which the program bit line voltage Vbl_pgm is provided.

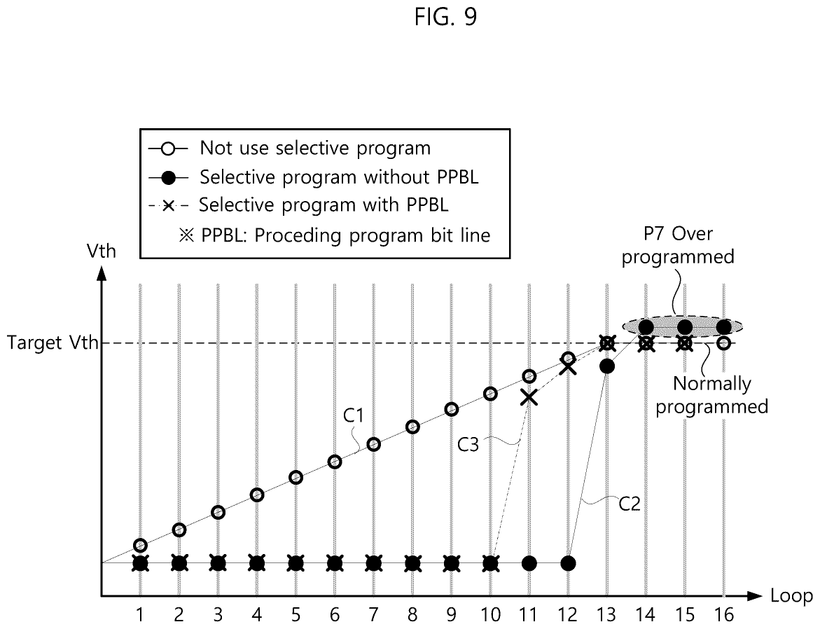

FIG. 9 is an example graph showing why the start loop in which the program bit line voltage described in FIG. 3 is applied must be faster than the loop in which the verification operation begins. A method in which the starting loop to which the program bit line voltage Vbl_pgm is applied is faster than the loop to which the verification operation starts is hereinafter referred to as the preceding program bit line PPBL. Referring to FIG. 9, over-programming that may occur when applying the selective program can be prevented by using the preceding program bit line PPBL. To simplify the explanation, memory cells programmed to the seventh target state P7 will be described as an example.

The curve C1 shows the change in threshold voltage when the selective program is not used for memory cells programmed to the seventh target state P7. That is, the curve C1 shows a case where the program bit line voltage Vbl_pgm is applied to the memory cells from the first loop Loop1 without setting the program inhibition. The threshold voltage of memory cells will gradually increase as the loop count increases due to the program bit line voltage Vbl_pgm applied from the first program loop Loop1. And when the 13th loop Loop13 is reached, most of the memory cells will have the target threshold voltage (Target Vth). In the subsequent loop, the target threshold voltage (Target Vth) is maintained as the inhibitory bit line voltage Vbl_inh is provided to the bit lines of the memory cells.

Curve C2 shows the case where the selective program is used, but the preceding program bit line PPBL is not applied. That is, memory cells programmed to the seventh target state P7 receive the inhibitory bit line voltage Vbl_inh from the first loop Loop1 to the twelfth loop Loop12. Also, when the program bit line voltage Vbl_pgm is provided from the 13th loop Loop13, the memory cells can be exposed to a relatively high program voltage. Accordingly, memory cells programmed to the seventh target state P7 in the fourteenth loop Loop14 may be overprogrammed.

Curve C3 shows the case where the selective program is used and the preceding program bit line PPBL is applied. Memory cells programmed to the seventh target state P7 receive the inhibitory bit line voltage Vbl_inh from the first loop Loop1 to the tenth loop Loop10. And when the program bit line voltage Vbl_pgm is provided from the 11th loop Loop11, the memory cells are exposed to a relatively low program voltage at the actual program start point compared to the curve C2. Accordingly, overprogramming of memory cells can be prevented.

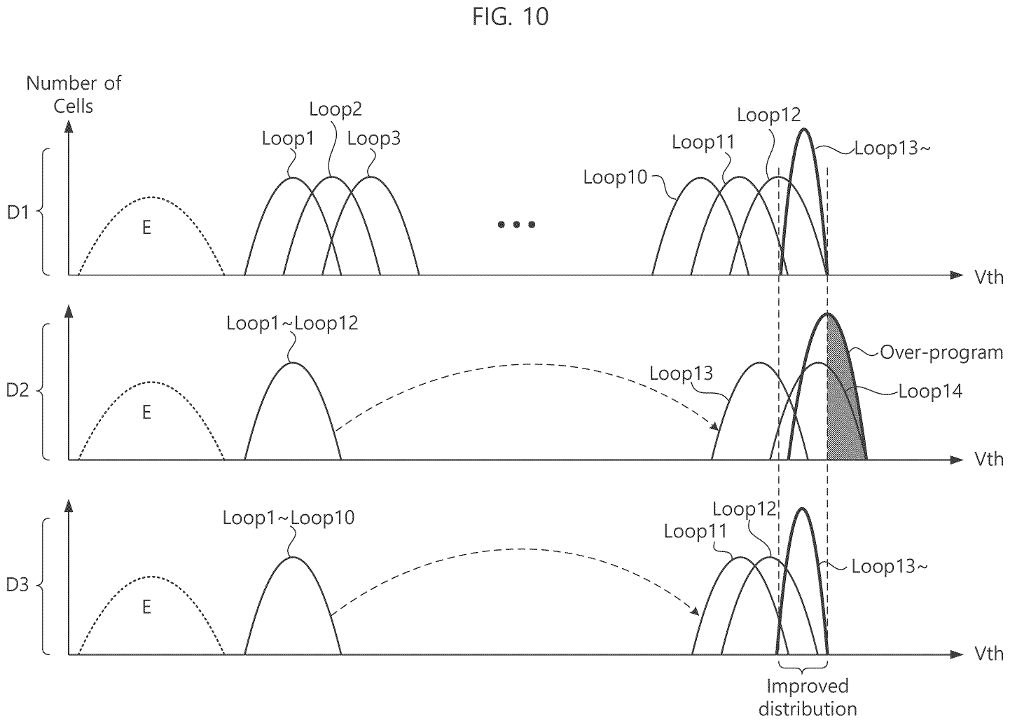

FIG. 10 is an example diagram showing changes in threshold voltage of memory cells corresponding to each curve in FIG. 9. Referring to FIG. 10, target state distribution of memory cells can be improved through selective program using the preceding program bit line PPBL.

D1 shows the change in distribution of memory cells when the selective program described in curve C1 of FIG. 9 is not used. In this case, it can be seen that the threshold voltage of the memory cells gradually increases with each loop. Due to the threshold voltage of the cells gradually increasing as the loop count increases, the threshold voltage distribution of the memory cells after the 13th loop Loop13 will form a desirable target distribution of the shape shown. However, since the bit lines of unprogrammed memory cells are set to the program bit line voltage in each loop, pass disturbance and large power consumption are inevitably accompanied.

D2 shows the change in threshold voltage distribution of memory cells when the selective program described in curve C2 of FIG. 9 is used, but the preceding program bit line PPBL is not applied. That is, the inhibitory bit line voltage Vbl_inh is provided to memory cells programmed to the seventh target state P7 from the first loop Loop1 to the twelfth loop Loop12. And when the program bit line voltage Vbl_pgm is provided from the 13th loop Loop13, memory cells may be exposed to a relatively high program voltage. Accordingly, memory cells programmed to the seventh target state P7 in the fourteenth loop Loop14 may be overprogrammed.

D3 shows the change in threshold voltage distribution of memory cells when the selective program described in curve C3 of FIG. 9 is used and the preceding program bit line PPBL is applied at the same time. Memory cells programmed to the seventh target state P7 receive the inhibitory bit line voltage Vbl_inh from the first loop Loop1 to the tenth loop Loop10. And when the program bit line voltage Vbl_pgm is provided from the 11th loop Loop11, the threshold voltage of the memory cells increases at a somewhat reduced extent. Therefore, by using the selective program, the range of change in the threshold voltage of memory cells can be controlled more precisely than D2, and overprogramming of memory cells can be prevented.

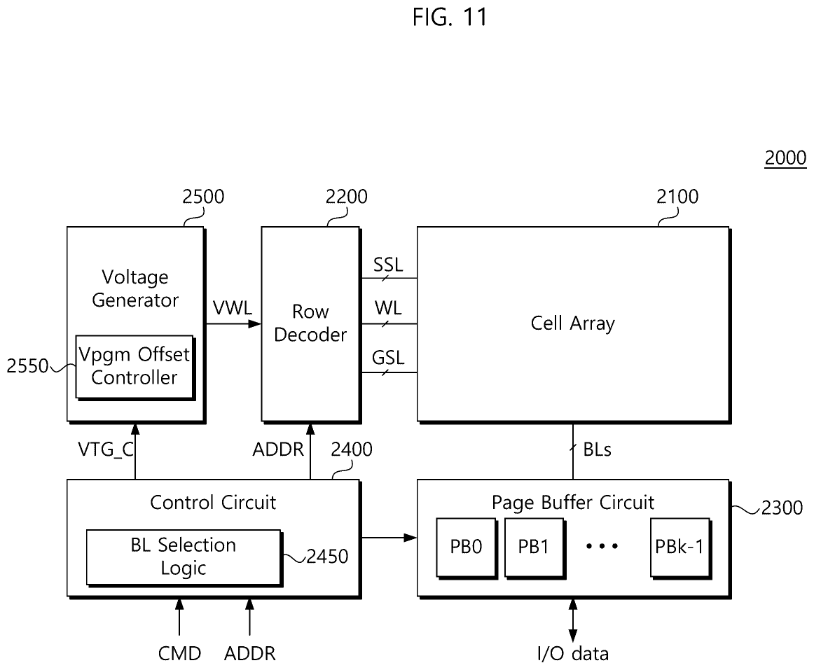

FIG. 11 is a block diagram showing an example of a non-volatile memory device. Referring to FIG. 11, the non-volatile memory device 2000 may include a cell array 2100, a row decoder 2200, a page buffer circuit 2300, a control circuit 2400, and a voltage generator 2500. Here, the cell array 2100, row decoder 2200, page buffer circuit 2300, and control circuit 2400 are substantially the same as those in FIG. 1. Therefore, descriptions of their functions or composition will be skipped.

The control circuit 2400 operates identically to the control circuit 1400 of FIG. 1. And the control circuit 2400 provides the program bit line voltage Vbl_pgm and the inhibitory bit line voltage Vbl_inh to the memory cells as described in the table of FIG. 3 by the bit line selection logic 2450. In practice, as the number of memory cells set to the program bit line voltage Vbl_pgm decreases, the program speed increases. The program speed will be relatively higher in the initial program loop where the number of bit lines set to the program bit line voltage Vbl_pgm is small.

The voltage generator 2500 supplies various types of word line voltages VWL to be supplied to each word line under the control of the control circuit 2400 and a voltage that will be supplied to the bulk (e.g., well area) where memory cells are formed. In particular, the voltage generator 2500 includes a program voltage offset controller 2550 to compensate for the program speed that increases as the number of memory cells whose bit lines are set to the program bit line voltage decreases. The program voltage offset controller 2550 adjusts the program start voltage to a value reduced by a predetermined voltage offset. Additionally, the program voltage offset controller 2550 may gradually reduce the size of the voltage offset as the number of program loops increases. When a specific program loop is reached, the program voltage offset controller 2550 provides an offset of ‘0’ and returns to the general ISPP method increment step AV. The method of adjusting the offset of the program voltage by the program voltage offset controller 2550 will be described in more detail through the drawings described later.

An increase in program speed due to a decrease in the number of program bit lines can be compensated for by the voltage generator 2500 including the program voltage offset controller 2550. The program voltage offset controller 2550 may apply the maximum voltage offset in the first program loop and then reduce the size of the voltage offset as the number of program loops increases.

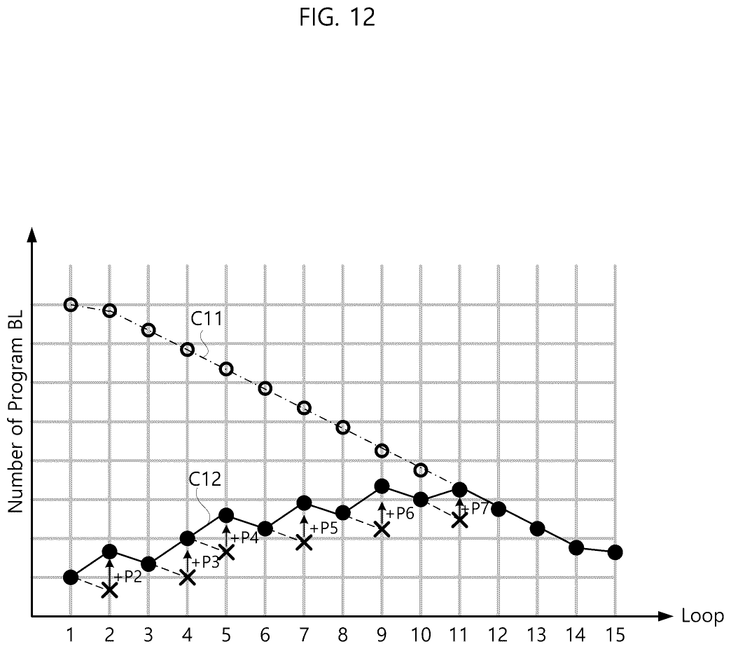

FIG. 12 is an example graph showing the number of program bit lines reduced according to the selective program. Referring to FIG. 12, curve C11 shows the number of program bit lines according to the program loop when the selective program is not applied. And the curve C12 shows the number of program bit lines according to the number of program loops when the selective program is applied.

According to the curve C11, in the first loop Loop1, all selected memory cells are set to program bit lines. As the program loop count increases, the number of memory cells identified as program passes by the verification operation will increase. Accordingly, as the number of inhibit bit lines increases with an increase in the program loop count, the number of program bit lines among selected memory cells decreases.

When the selective program is applied, as shown in curve C12, the smaller the loop count, the smaller the number of program bit lines. That is, the number of program bit lines in the first loop Loop1 is minimal. This is because, in the first loop Loop1, only the memory cells programmed to the first target state P1 are set to the program bit line voltage, and the memory cells programmed to the erase state E and the second to seventh target states P2 to P7 are set to the program inhibitory bit line voltage. And in the second loop Loop2, memory cells programmed to the second target state P2 are added to the set of program bit line voltage. In this way, as the program loop count increases, the number of program bit lines generally increases up to the 11th loop Loop11.

And after the 11th loop Loop11, there are no memory cells set to the inhibit state before the program. Accordingly, the number of program bit lines will gradually decrease after the 11th loop Loop11.

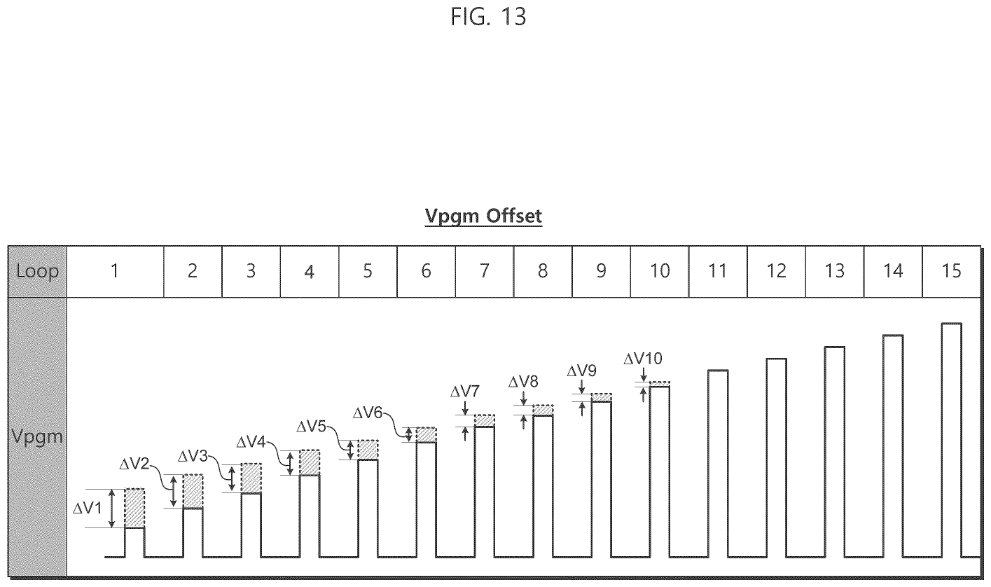

FIG. 13 shows the waveform of an example program voltage pulse provided to selected memory cells in each program loop when applying the voltage offset. Referring to FIG. 13, a voltage offset (ΔVi, i is the loop count) that decreases as the loop count increases is applied. As a result, the smaller the number of program loops, the relatively lower the level of the program voltage.

The program voltage Vpgm in the first loop Loop1 is provided in a level reduced by the first voltage offset ΔV1 compared to the program start voltage applied in general incremental step pulse programming ISPP. The program voltage Vpgm in the second loop Loop2 is provided at a level lower than the program voltage applied in the general ISPP by the second voltage offset ΔV2. The voltage offset of the program voltage Vpgm gradually decreases for each program loop from the third loop Loop3 to the tenth loop Loop10.

The increase in program speed resulting from a decrease in the number of program bit lines can be compensated by providing the program voltage Vpgm to which the voltage offset is applied. Therefore, even if the selective programming is applied, the program speed for memory cells can be controlled the same as when applying the general ISPP.

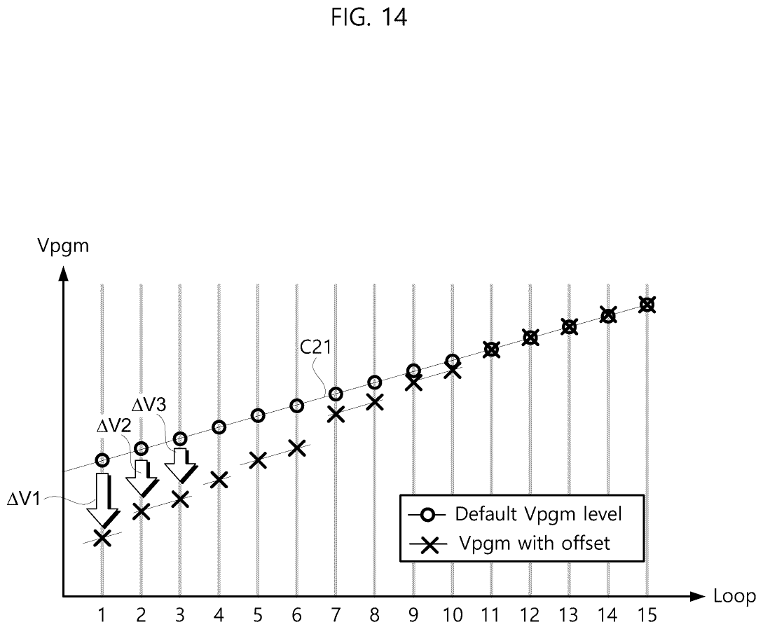

FIG. 14 is an example graph showing the change in a level of the program voltage to which the voltage offset is applied according to the program loop. Referring to FIG. 14, the program voltage offset controller 2550 (see FIG. 11) may apply the maximum voltage offset in the initial loop and reduce the size of the voltage offset as the loop count increases.

The curve C21 shows the change in program voltage depending on the loop count when applying the general ISPP method. According to the selective programming method applying the voltage offset, the program voltage Vpgm in the first loop Loop1 is provided at a level reduced by the first voltage offset ΔV1 compared to the program start voltage (or default start voltage) applied in the general ISPP. The program voltage Vpgm in the second loop Loop2 is provided at a level lower than the default program voltage applied in a general ISPP by the second voltage offset ΔV2. The voltage offset of the program voltage Vpgm gradually decreases for each loop from the third loop Loop3 to the tenth loop Loop10

The increase in program speed resulting from a decrease in the number of program bit lines can be compensated by providing a program voltage Vpgm to which this gradually decreasing voltage offset is applied.

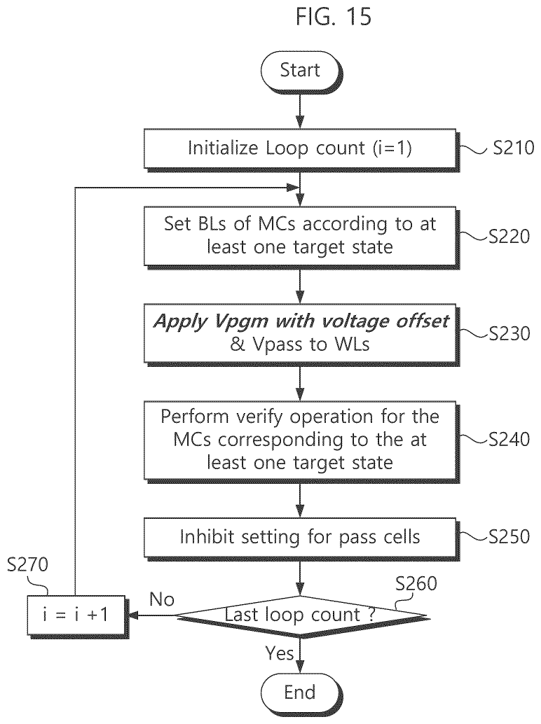

FIG. 15 is a flowchart showing an example of a programming method performed in the non-volatile memory device of FIG. 11. According to FIG. 15, except for step S230, each of the remaining steps are substantially the same as those in FIG. 8. Therefore, description of the remaining steps except step S230 will be skipped.

In step S230, the program voltage offset controller 2550 will adjust the program voltage Vpgm by subtracting the voltage offset allocated to the corresponding program loop. Then, the program voltage Vpgm adjusted by the voltage offset is applied to the word lines of the selected memory cells. At the same time, a pass voltage Vpass will be provided to the unselected word lines. The program voltage Vpgm to which the voltage offset is applied may be adjusted as shown in FIG. 13 or FIG. 14 described above.

In some implementations, the program bit line voltage is provided to only some of the memory cells selected for programming. Accordingly, pass disturbance of memory cells that occurs when the program bit line voltage is provided can be reduced. In addition, the word line setup power generated during program operation can also be reduced due to a reduction in capacitance between the word line and the channel based on the program bit line voltage. In addition, by applying a voltage offset to compensate for the program speed, the increase in program speed due to a decrease in the number of program bit lines can be compensated.

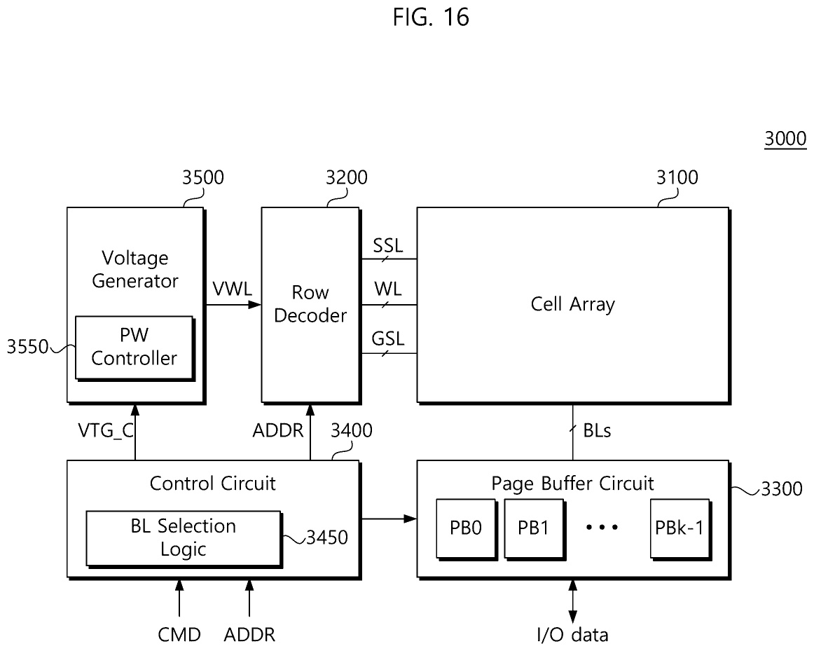

FIG. 16 is a block diagram showing an example of a non-volatile memory device. Referring to FIG. 16, the non-volatile memory device 3000 may include a cell array 3100, a row decoder 3200, a page buffer circuit 3300, a control circuit 3400, and a voltage generator 3500. Here, the cell array 3100, row decoder 3200, page buffer circuit 3300, and control circuit 3400 are substantially the same as those in FIGS. 1 and 11. Therefore, detailed descriptions of their functions or composition will be omitted.

The control circuit 3400 operates identically to the control circuit 2400 of FIG. 11. And the control circuit 3400 provides the program bit line voltage Vbl_pgm and the inhibitory bit line voltage Vbl_inh to the memory cells as described in the table of FIG. 3 by the bit line selection logic 3450. In reality, as the number of memory cells to which the program bit line voltage Vbl_pgm is applied decreases, the program speed increases. The program speed will be relatively higher in the initial program loop where the number of memory cells set to the program bit line voltage Vbl_pgm is small.

The voltage generator 3500 generates various types of word line voltages VWL to be supplied to each word line and a voltage to the bulk (e.g., well area) where memory cells are formed under the control of the control circuit 3400. In particular, the voltage generator 3500 includes a pulse width controller 3550 to compensate for the program speed that increases as the number of memory cells set to the program bit line voltage Vbl_pgm decreases. The pulse width controller 3550 can adjust the pulse width of the program voltage Vpgm. The pulse width controller 3550 applies a program pulse with the largest pulse width offset (ΔWi, ‘I’ is the loop count) in the first program loop. That is, the pulse width controller 3550 will provide a program pulse with a size obtained by subtracting the pulse width offset ΔWi from the default pulse width PW for each program loop. As the program loop increases, the pulse width controller 3550 may gradually reduce the size of the pulse width offset ΔWi. When a specific program loop is reached, the pulse width controller 3550 provides a pulse width offset of ‘0’ to return to the default pulse width PW of the general ISPP method. The method of adjusting the pulse width offset of the program voltage by the pulse width controller 3550 will be described in more detail through the drawings described later.

By using the voltage generator 3500 including the pulse width controller 3550, an increase in program speed due to a decrease in the number of program bit lines can be compensated for by reducing the time for which the program voltage is applied. The pulse width controller 3550 applies the program voltage of the minimum pulse width in the first loop. And as the number of program loops increases, the pulse width controller 3550 can restore the pulse width of the program pulse to the default pulse width.

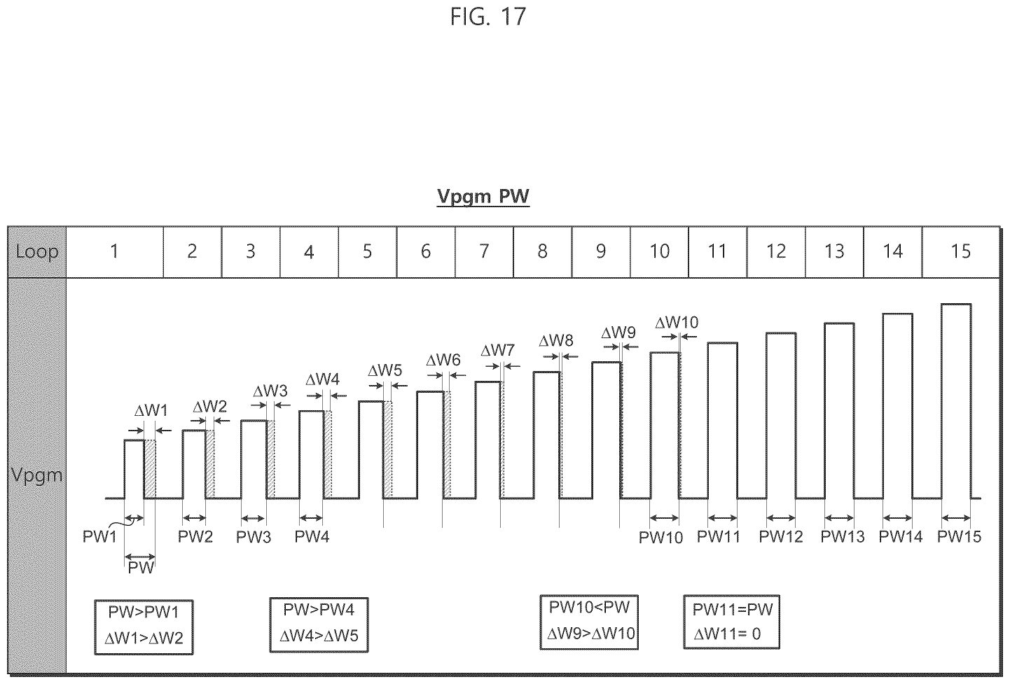

FIG. 17 shows the form of an example program voltage pulse provided to selected memory cells in each program loop when applying the pulse width offset. Referring to FIG. 17, a pulse width offset (ΔWi, ‘I’ is the loop count) that decreases as the loop count increases is applied. Therefore, the pulse width of the program voltage provided in the program start loop is the narrowest, and as the number of program loops increases, the pulse width of the program voltage becomes relatively wider.

The program voltage Vpgm pulse width PW1(=PW-ΔW1) in the first loop Loop1 where the program start voltage is applied is reduced from the default pulse width PW by the first pulse width offset AW1. The pulse width PW2 of the program voltage Vpgm in the second loop Loop2 is provided in a size (PW-ΔW2) reduced from the default pulse width PW by the second pulse width offset AW2. The pulse width PW3 of the program voltage Vpgm in the third loop Loop3 is provided in a size (PW-ΔW3) reduced by the third pulse width offset AW3 from the default pulse width PW. The pulse width PW4 of the program voltage Vpgm in the fourth loop Loop4 is provided in a size (PW-ΔW4) reduced by the fourth pulse width offset AW4 from the default pulse width PW. The pulse width offset ΔWi gradually decreases as the loop count increases, and may converge to ‘0’ in a specific loop (for example, Loop11).

As described above, an increase in program speed due to the decrease in the number of program bit lines can be compensated for by the program voltage Vpgm to which a gradually decreasing pulse width offset ΔWi is applied. Therefore, even if the selective programming method is applied, the program speed for memory cells can be controlled the same as when applying the general ISPP method.

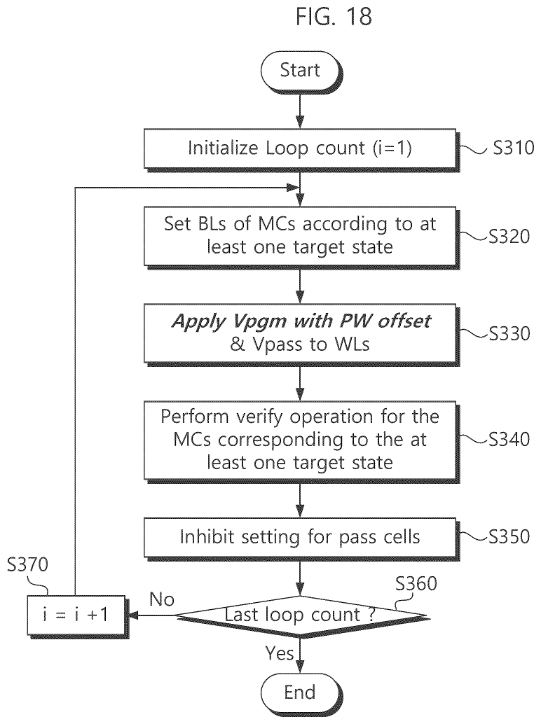

FIG. 18 is a flowchart showing an example of a programming method performed in the non-volatile memory device of FIG. 16. According to FIG. 18, except for step S330, each of the remaining steps are substantially the same as those in FIG. 15. Therefore, description of the steps except step S330 will be omitted.

In step S330, the pulse width controller 3550 will generate a program voltage Vpgm with a size obtained by subtracting the pulse width offset ΔWi allocated in the corresponding loop. Then, the program voltage Vpgm adjusted by the pulse width offset ΔWi is applied to the word lines of the selected memory cells. At the same time, a pass voltage Vpass will be provided to the unselected word lines. The program voltage Vpgm to which the pulse width offset ΔWi is applied may be adjusted as shown in FIG. 17 described above.

In some implementations, the program bit line voltage Vbl_pgm is provided to only some of the selected memory cells. Accordingly, pass disturbance of memory cells that occurs when the program bit line voltage Vbl_pgm is provided can be reduced. In addition, the word line setup power generated during program operation may also be reduced due to a reduction in capacitance between the word line and the channel based on the program bit line voltage Vbl_pgm. In addition, an increase in program speed can be compensated by using the program voltage Vpgm to which the pulse width offset ΔWi is applied to compensate for the program speed.

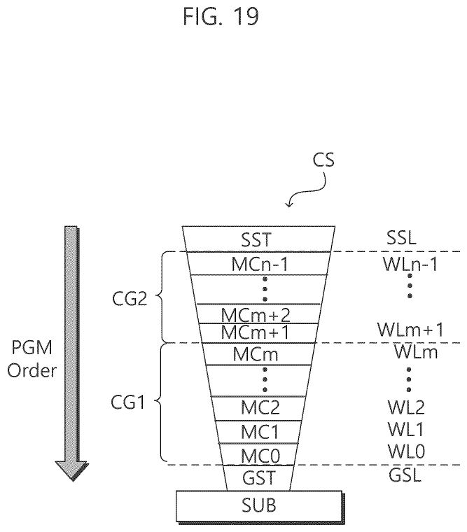

FIG. 19 is a diagram illustrating example memory cells comprised by the cell string CS of FIG. 2 and their program order. Referring to FIG. 19, in the cell string CS, the memory cells are programmed to the order from memory cells located farthest from the substrate SUB to memory cells closer to the substrate SUB. However, the program order may be reversed depending on various purposes. Here, one cell string CS may include a plurality of memory cells (MC0 to MCn−1, n is a natural number greater than 1). For example, the memory cell MC0 is the memory cell closest to the substrate, and the memory cell MCn−1 is the memory cell furthest from the substrate.

As the distance from the cell string CS to the substrate SUB increases, the size of the memory cell increases. Depending on the size of the memory cell, memory cells may be grouped into two cell groups (CG1, CG2) or more groups. This type is a method of forming a greater number of memory cells in one cell string CS to increase the integration of vertical NAND flash memory. The first cell group CG1 may include memory cells MC0 to MCm whose sizes increase in order. The second cell group CG2 may include memory cells MCm+1 to MCn−1 whose sizes increase in order. Starting with the memory cell MCn−1 located at a relatively long distance from the substrate SUB, the memory cell MC0 is programmed last.

In the above-described structure, the loop count in which the program is activated or the loop count in which the verification operation is activated can be determined for each target state depending on which cell group the word line selected for the program corresponds to.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The above are implementations for carrying out the present disclosure. In addition to the above-described implementations, the present disclosure may include simple design changes or easily changeable implementations. In addition, the present disclosure will include techniques that can be easily modified and implemented using the implementations. Therefore, the scope of the present disclosure should not be limited to the above-described implementations, and should be defined by the claims and equivalents of the claims of the present disclosure as well as the claims to be described later.

What is claimed is:

1. A method of programming a non-volatile memory device for programming memory cells with a plurality of target states, comprising:
executing a first program loop, wherein in the first program loop a first program voltage is applied to a word line based on a plurality of bit lines of a first plurality of memory cells being set to an inhibitory bit line voltage, the first plurality of memory cells programmed to a first target state; and
after executing the first program loop, executing a second program loop, wherein in the second program loop a second program voltage is applied to the word line based on the plurality of bit lines of the first plurality of memory cells being set to a program bit line voltage.

2. The method of claim 1, wherein the first target state corresponds to any one of the plurality of target states excluding an erase state and a lowest program state.

3. The method of claim 2, wherein a second plurality of memory cells programmed to the lowest program state receive the program bit line voltage from the first program loop.

4. The method of claim 1, comprising:
after executing the second program loop, executing a third program loop, wherein in the third program loop a third program voltage is applied to the word line based on the plurality of bit lines of the first plurality of memory cells being set to the program bit line voltage,
wherein a verification operation for the first plurality of memory cells in the second program loop is deactivated, and the verification operation is activated in the third program loop.

5. The method of claim 4, wherein a plurality of bit lines of a third plurality of memory cells in the second program loop are set to the inhibitory bit line voltage, the third plurality of memory cells being programmed to a second target state higher than the first target state.

6. The method of claim 1, wherein a pulse level of the first program voltage provided in the first program loop is provided based on subtracting a first voltage offset from a level of a first default voltage, the first default voltage corresponding to the first program loop.

7. The method of claim 6, wherein a pulse level of the second program voltage provided in the second program loop is provided based on subtracting a second voltage offset from a level of a second default voltage, the second default voltage corresponding to the second program loop, and
wherein the second voltage offset is smaller than the first voltage offset.

8. The method of claim 1, wherein a pulse width of the first program voltage provided in the first program loop is narrower than a pulse width of the second program voltage provided in the second program loop.

9. A non-volatile memory device, comprising:
a cell array including a plurality of memory cells connected to a plurality of bit lines;
a row decoder configured to transfer a program voltage or a pass voltage to a plurality of word lines of the plurality of memory cells during a program operation;
a page buffer configured to set the plurality of bit lines to a program bit line voltage or an inhibitory bit line voltage; and
a control circuit configured to
control the page buffer and the row decoder to provide an inhibit bit line voltage to a plurality of bit lines of a first plurality of memory cells during an inhibit loop period, and
to provide the program bit line voltage to the plurality of bit lines of the first plurality of memory cells during a program loop period following the inhibit loop period, the inhibit loop period including an initial program loop of the first plurality of memory cells programmed to a first target state.

10. The device of claim 9, wherein the first target state corresponds to any one program state other than an erase state and a lowest program state among a plurality of program states.

11. The device of claim 10, wherein the control circuit is configured to control the page buffer to provide the program bit line voltage from a first program loop to a plurality of bit lines of a second plurality of memory cells, the second plurality of memory cells being programmed to the lowest program state.

12. The device of claim 9, wherein the program loop period includes a plurality of consecutive program loops, and the device is configured to deactivate a program verification operation in a program loop that is performed first among the plurality of consecutive program loops.

13. The device of claim 9, comprising:
a voltage generator configured to generate and transmit the program voltage to the row decoder,
wherein the voltage generator is configured to apply a voltage offset or a pulse width offset to the program voltage, and the voltage offset or the pulse width offset varies based on a loop count.

14. The device of claim 13, wherein the voltage generator is configured to generate a program voltage level based on subtracting the voltage offset from a default voltage level, and the voltage offset increases as the loop count decreases.

15. The device of claim 13, wherein the voltage generator is configured to adjust a pulse width of the program voltage based on subtracting the pulse width offset from a default pulse width, and the pulse width offset increases as the loop count decreases.

16. A method of programming a non-volatile memory device for programming selected memory cells to a plurality of target states, the method comprising:
executing at least one program loop, wherein a plurality of bit lines of a plurality of memory cells is set to an inhibitory bit line voltage during a first loop period, the plurality of memory cells programmed to a first target state; and
executing a plurality of program loops, wherein the plurality of bit lines of the plurality of memory cells is set to a program bit line voltage during a second loop period following the first loop period.

17. The method of claim 16, wherein the at least one program loop includes a program start loop.

18. The method of claim 17, wherein a level of a program pulse provided from the at least one program loop is lower than a level of a default program pulse by a specific voltage offset.

19. The method of claim 17, wherein a pulse width of a program pulse provided from the at least one program loop is narrower than a pulse width of a default program pulse by a specific pulse width offset.

20. The method of claim 16, wherein the plurality of program loops included in the second loop period include a first program loop and at least one second program loop that follows the first program loop, a verification operation is deactivated in the first program loop, and the verification operation is activated in the at least one second program loop.
